(19) United States
(12) Patent Application Publication
(10) Pub. No.: US 2026/0059888 A1
(43) Pub. Date: Feb. 26, 2026

(54) PHOTOELECTRIC PACKAGING STRUCTURE, MANUFACTURING METHOD, AND CAMERA MODULE

(71) Applicant: Triple Win Technology (Shezhen) Co.Ltd., Shenzhen (CN)

(72) Inventors: HUNG-TA LI, New Taipei (TW); Hsin-Yen Hsu, New Taipei (TW); Tzu-Li Feng, New Taipei (TW); Yi-Mou Huang, New Taipei (TW)

(21) Appl. No.: 19/248,997

(22) Filed: Jun. 25, 2025

(30) Foreign Application Priority Data
Aug. 22, 2024 (CN) 202411159141.8

(51) Int. Cl. H10F 39/00

(52) U.S. Cl. CPC H10F 39/811; H10F 39/011; H10F 39/804

(57) ABSTRACT

A photoelectric packaging structure, manufacturing method, and camera module are provided. The structure includes a substrate module, a photosensitive chip, and a plastic packaging module. The substrate module includes a glass substrate and a first conductive structure with a first conductive pad. The photosensitive chip and the plastic packaging module are located on the substrate module. The plastic packaging module includes a packaging body and a second conductive structure. The second conductive structure includes a first and a second conductive channels, a second and a third conductive pads. The first and the second conductive channels are located in the packaging body. The first conductive channel is connected to the first and the second conductive pads. The second conductive channel is connected to the photosensitive chip and the third conductive pad. The second conductive pad is connected to the third conductive pad, thereby connecting the photosensitive chip to the substrate module.

### CROSS-REFERENCE TO RELATED APPLICATION

This application claims the benefit and priority to Chinese Patent Application Serial No. 202411159141.8, filed on Aug. 22, 2024, entitled “PHOTOELECTRIC PACKAGING STRUCTURE, MANUFACTURING METHOD, AND CAMERA MODULE”, and the content of which is hereby fully incorporated by reference.

### FIELD

The subject matter herein generally relates to semiconductor packages, and more particularly, to a photoelectric packaging structure, a manufacturing method of the photoelectric packaging structure, and a camera module with the photoelectric packaging structure.

### BACKGROUND

Camera modules may include circuit boards and photosensitive chips mounted on the circuit boards. The photosensitive chip may be connected to conductive pads of the circuit board through a wire bonding technology.

However, a wire bonding tool needs a certain space between the photosensitive chip and the conductive pad of the circuit board when operated, which results in an increase in the lateral size between the photosensitive chip and the conductive pad. Furthermore, a line width and a line spacing of the circuit board are limited by process factors and difficult to be reduced, which is not conducive to the miniaturization development of the camera module. Moreover, heat treatment is involved in each of the circuit board manufacturing process and the wire bonding process, and the circuit board is easily deformed at high temperatures, which lowers the quality of the camera module. Improvements in the art are desired.

### BRIEF DESCRIPTION OF THE DRAWINGS

FIG. 1 is a block diagram of a camera module according to an embodiment of the present disclosure.

FIG. 2 is a diagrammatic view of a photoelectric packaging structure of the camera module shown in FIG. 1.

FIG. 3 is a diagrammatic view of a first glass substrate according to an embodiment of the present disclosure.

FIG. 4 is a diagrammatic view showing a seed layer formed on the first glass substrate shown in FIG. 3.

FIG. 5 is a diagrammatic view showing a mask formed on the first glass substrate shown in FIG. 4.

FIG. 6 is a diagrammatic view showing the seed layer etched through the mask shown in FIG. 5.

FIG. 7 is a diagrammatic view showing the mask shown in FIG. 6 removed.

FIG. 8 is a diagrammatic view showing a conductive material formed on the remaining seed layer shown in FIG. 7.

FIG. 9 is a diagrammatic view showing a protective film formed on the first glass substrate shown in FIG. 8 to obtain a substrate module.

FIG. 10 is a diagrammatic view showing a photosensitive chip and an electronic component formed on the substrate module shown in FIG. 9.

FIG. 11 is a diagrammatic view showing a first packaging block formed on the substrate module shown in FIG. 10.

FIG. 12 is a diagrammatic view showing a second packaging block formed on the first packaging block shown in FIG. 11 and a hollow channel defined in the second packaging block.

FIG. 13 is a diagrammatic view showing a mask formed on the photosensitive chip shown in FIG. 12.

FIG. 14 is a diagrammatic view showing a conductive material formed in the hollow channel shown in FIG. 13.

FIG. 15 is a diagrammatic view showing the mask shown in FIG. 14 removed to obtain an intermediate body.

FIG. 16 is a diagrammatic view of a glass cover plate with a mask according to an embodiment of the present disclosure.

FIG. 17 is a diagrammatic view showing a conductive material formed on the glass cover plate through the mask shown in FIG. 16.

FIG. 18 is a diagrammatic view showing the mask shown in FIG. 17 removed.

FIG. 19 is a diagrammatic view showing a mask formed on the glass cover plate shown in FIG. 18.

FIG. 20 is a diagrammatic view showing the glass cover plate shown in FIG. 19 etched through the mask and the mask removed to obtain a cover module.

FIG. 21 is a diagrammatic view showing the cover module shown in FIG. 20 installed onto the intermediate body shown in FIG. 15.

FIG. 22 is a diagrammatic view showing solder balls formed on the substrate module shown in FIG. 21.

FIG. 23 is a diagrammatic view showing the cover module shown in FIG. 21 processed and a sealing material formed between the cover module and the intermediate body.

FIG. 24 is a diagrammatic view showing a protective layer formed on the first glass substrate shown in FIG. 3 according to another embodiment of the present disclosure.

FIG. 25 is a diagrammatic view showing a seed layer formed on the protective layer shown in FIG. 24.

FIG. 26 is a diagrammatic view showing a mask formed on the seed layer shown in FIG. 25.

FIG. 27 is a diagrammatic view showing the seed layer shown in FIG. 26 etched through the mask.

FIG. 28 is a diagrammatic view showing the mask shown in FIG. 27 removed and a conductive material formed on the remaining seed layer.

FIG. 29 is a diagrammatic view showing a protective layer formed on the first glass substrate shown in FIG. 28 to obtain a substrate module.

FIG. 30 is a diagrammatic view showing a packaging body formed on the substrate module shown in FIG. 29 and the cover module shown in FIG. 20 installed on the substrate module to obtain a photoelectric packaging structure.

FIG. 31 is a diagrammatic view of a glass cover plate with a protective film according to another embodiment of the present disclosure.

FIG. 32 is a diagrammatic view showing the glass cover plate shown in FIG. 31 etched through the protective film.

FIG. 33 is a diagrammatic view showing a conductive material formed in the protective film shown in FIG. 32 to obtain a cover module.

FIG. 34 is a diagrammatic view showing the cover module shown in FIG. 33 installed onto the intermediate body shown in FIG. 15 to obtain a photoelectric packaging structure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

### First Embodiment

Referring to FIG. 1, a camera module 1 is provided according to an embodiment of the present disclosure. The camera module 1 includes a lens assembly 2 and a photoelectric packaging structure 100. The lens assembly 2 has an optical path for an external light beam to pass through. The photoelectric packaging structure 100 receives the external light beam passing through the lens assembly 2 to form an optical signal, and then converts the optical signal into electrical signal to realize photoelectric conversion.

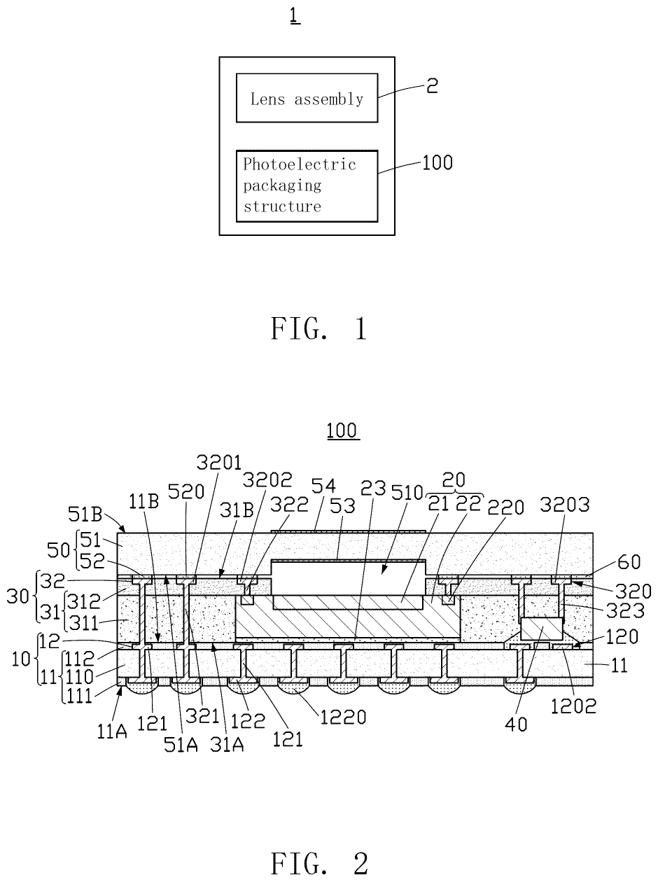

Referring to FIG. 2, the photoelectric packaging structure 100 includes a substrate module 10, a photosensitive chip 20, and a plastic packaging module 30. The substrate module 10 includes a glass substrate 11 and a first conductive structure 12 formed in the glass substrate 11. The glass substrate 11 includes a first surface 11A and a second surface 11B opposite to each other. The first conductive structure 12 includes a first wiring layer 120. The first wiring layer 120 is exposed from the second surface 11B and includes a first conductive pad 1201. In some embodiments, the first conductive structure 12 includes a conductive material, and the conductive material may be a conductive ink or a metal material. The conductive ink may include at least one element selected from a group consisting of silver, platinum, gold, copper, nickel, aluminum, and any combination thereof. The metal material may be silver, copper, or gold.

The photosensitive chip 20 is located on the second surface 11B. The photosensitive chip 20 includes a photosensitive area 21 and a non-photosensitive area 22 connected to each other. The photosensitive area 21 receives the optical signal formed by the external light beam passing through the lens assembly 2, and then converts the optical signal into the electrical signal. The non-photosensitive area 22 may surround the photosensitive area 21. A connection pad 220 (such as an aluminum pad) may be provided on the non-photosensitive area 22. In some embodiments, the photosensitive chip 20 may be fixed to the second surface 11B through an adhesive layer 23.

The plastic packaging module 30 is located on the second surface 11B. The plastic packaging module 30 includes a packaging body 31 and a second conductive structure 32 formed in the packaging body 31. The packaging body 31 covers at least a sidewall of the photosensitive chip 20, and the photosensitive area 21 of the photosensitive chip 20 is exposed from the packaging body 31. The packaging body 31 can improve the stability of the photosensitive chip 20. The packaging body 31 includes a third surface 31A facing the second surface 11B and a fourth surface 31B opposite to the third surface 31A. The second conductive structure 32 includes a first conductive channel 321, a second conductive channel 322, and a second wiring layer 320. Each of the first conductive channel 321 and the second conductive channel 322 is formed in the packaging body 31, and may extend along a thickness direction of the packaging body 31. The second wiring layer 320 is exposed from the fourth surface 31B. The second wiring layer 320 includes a second conductive pad 3201 and a third conductive pad 3202. The second conductive pad 3201 and the third conductive pad 3202 redistribute the connection pad 220 of the non-photosensitive region 22 through a Redistribution Layer (RDL) process, thereby transmitting the electrical signal of the photosensitive chip 20 to the substrate module 10. The specific positions of the second conductive pad 3201 and the third conductive pad 3202 on the packaging body 31 may be adjusted. Two ends of the first conductive channel 321 are connected to the first conductive pad 1201 and the second conductive pad 3201, respectively. Two ends of the second conductive channel 322 are connected to the connection pad 220 of the non-photosensitive area 22 and the third conductive pad 3202, respectively. The second conductive pad 3201 and the third conductive pad 3202 may be electrically connected to each other through the wiring patterns of the second wiring layer 320, thereby achieving electrical connection between the photosensitive chip 20 and the substrate module 10. As such, the electrical signal generated by the photosensitive chip 20 is transmitted to the first conductive structure 12 through the second conductive channel 322, the third conductive pad 3202, the second conductive pad 3201, and the first conductive channel 321. In some embodiments, the second conductive structure 32 includes a conductive material, and the conductive material may be a conductive ink or a metal material. The second conductive structure 32 may be formed by defining a hollow channel in the packaging body 31 and filling the conductive material into the hollow channel. For example, the hollow channel may be completely filled with the conductive material to form the first conductive channel 321 and the second conductive channel 322. In other embodiments, a conductive layer, which is formed by solidifying the conductive material, may be formed on the inner wall of the hollow channel, thereby forming the first conductive channel 321 and the second conductive channel 322 that are hollow. In the embodiment, the conductive material is filled in the hollow channel by conductive ink spraying or copper electroplating.

In some embodiments, the packaging body 31 includes a first packaging block 311 and a second packaging block 312. The first packaging block 311 is located on the second surface 11B and at least adheres to the sidewall of the photosensitive chip 20. The second packaging block 312 is located on the first packaging block 311 and covers the non-photosensitive area 22 of the photosensitive chip 20. A surface of the first packaging block 311 away from the second packaging block 312 is the third surface 31A, and a surface of the second packaging block 312 away from the first packaging block 311 is the fourth surface 31B. At this time, the first conductive channel 321 is formed in the first packaging block 311 and the second packaging block 312, and the second conductive channel 322 is formed in the second packaging block 312. In some embodiments, the first packaging block 311 includes at least one of an epoxy resin and a phenolic resin, and the second packaging block 312 includes at least one of a polyimide adhesive and a Build-up Film. In other embodiments, the packaging body 31 may also be a one-piece structure.

In the photoelectric packaging structure 100 of the present disclosure, the packaging body 31 is provided on the substrate module 10 containing the first conductive pad 1201. The hollow channel corresponding to the first conductive pad 1201 is defined in the packaging body 31, and the conductive material is filled in the hollow channel to form the first conductive structure 12, thereby causing the first conductive structure 12 to electrically connect to the first conductive pad 1201 through the first conductive channel 321. Moreover, the first conductive structure 12 is further connected to the non-photosensitive area 22 of the photosensitive chip 20 through the second conductive channel 322 and the third conductive pad 3202, thereby achieving the electrical connection between the photosensitive chip 20 and the substrate module 10. The present disclosure eliminates the metal wires for electrically connecting the photosensitive chip 20 to the substrate module 10, so there is no need to reserve the space required for wire bonding tool, which is beneficial for reducing the lateral size of the photoelectric packaging structure 100 and conducive to the miniaturization of the photoelectric packaging structure 100. Moreover, compared with the existing circuit board wiring process and the wire bonding packaging process, the present disclosure uses the glass substrate 11 as the carrier of the photoelectric packaging structure 100, and the first conductive structure 12 is formed by defining the hollow channel in the packaging body 31 and filling the conductive material in the hollow channel, which is conducive to reducing the warpage and deformation of the carrier and improving the quality of the photoelectric packaging structure 100.

In some embodiments, the first wiring layer 120 may further include a first solder pad 1202. The photoelectric packaging structure 100 further includes an electronic component 40 mounted on the first solder pad 1202, and the packaging body 31 further covers the electronic component 40. The second conductive structure 32 further includes a third conductive channel 323, and the third conductive channel 323 is formed in the packaging body 31. The second wiring layer 320 further includes a fourth conductive pad 3203, and the fourth conductive pad 3203 is exposed from the fourth surface 31B. Two ends of the third conductive channel 323 are connected to the electronic component 40 and the fourth conductive pad 3203, respectively, thereby electrically connecting the fourth conductive pad 3203 to the first conductive pad 1201. The fourth conductive pad 3203 may also be electrically connected to the third conductive pad 3202. The third conductive pad 3202 and the fourth conductive pad 3203 redistribute the connection pad 220 of the non-photosensitive region 22 through the RDL process, to sequentially transmit the electrical signal of the photosensitive chip 20 to the electronic component 40 and the substrate module 10. As such, the electrical signal generated by the photosensitive chip 20 may also be transmitted to the first conductive structure 12 through the second conductive channel 322, the third conductive pad 3202, the fourth conductive pad 3203, and the third conductive channel 323, thereby achieving the electrical connection between the photosensitive chip 20 and the substrate module 10. The electronic component 40 may be a passive component or an active component. The passive component includes a resistor, a capacitor, etc. The active component includes a transistor, an integrated circuit, a picture tube, etc.

The first conductive structure 12 may also include a fourth conductive channel 121 and a second solder pad 122. The fourth conductive channel 121 is formed in the glass substrate 11, and the second solder pad 122 is exposed from the first surface 11A. One end of the fourth conductive channel 121 is selectively connected to the first conductive pad 1201 or the first solder pad 1202, and another end of the fourth conductive channel 121 is connected to the second solder pad 122. A solder ball 1220 may be provided on the second solder pad 122, and another component (such as a circuit board or a chip) may be mounted on the solder ball 1220, such that the electrical signal of the photosensitive chip 20 transmitted to the first conductive structure 12 can further be transmitted to the another component through the solder ball 1220. The solder ball 1220 may be tin ball. The first conductive structure 12 may be formed by defining a hollow channel in the packaging body 31 and filling a conductive material in the hollow channel. For example, the hollow channel may be completely filled with the conductive material to form the fourth conductive channel 121. In other embodiments, a conductive layer, which is formed by solidifying the conductive material, may also be formed on the inner wall of the hollow channel, thereby forming the fourth conductive channel 121 that is hollow. In the embodiment, the conductive material is formed by conductive ink spraying.

Furthermore, the glass substrate 11 may include a first glass body 110, a first protective film 111, and a second protective film 112. The first glass body 110 is located between the first protective film 111 and the second protective film 112. The first glass body 110 serves as a carrier for the fourth conductive channel 121, and the fourth conductive channel 121 is formed in the first glass body 110. The first protective film 111 and the second protective film 112 provide insulation protection for the first glass body 110. The first protective film 111 covers a sidewall of the first solder pad 1202, and the second protective film 112 covers a sidewall of the first conductive pad 1201. A surface of the first protective film 111 away from the first glass body 110 is the first surface 11A, and a surface of the second protective film 112 away from the first glass body 110 is the second surface 11B. In some embodiments, each of the first protective film 111 and the second protective film 112 may include a polyimide or a Build-up Film.

In some embodiments, the photoelectric packaging structure 100 further includes a cover module 50. The cover module 50 is located on the fourth surface 31B and covers the photosensitive chip 20. The cover module 50 includes a glass cover plate 51 and a third wiring layer 52 formed on the glass cover plate 51. The glass cover plate 51 includes a fifth surface 51A facing the fourth surface 31B and a sixth surface 51B opposite to the fifth surface 51A. The third wiring layer 52 is exposed from the fifth surface 51A and includes a fifth conductive pad 520. The fifth conductive pad 520 is selectively connected to the second conductive pad 3201 or the third conductive pad 3202, thereby electrically connecting the photosensitive chip 20 to the substrate module 10. The cover module 50 can protect the photosensitive area 21 of the photosensitive chip 20, and reduce the damage to the photosensitive area 21 under an external force. The lens assembly 2 may be installed on the cover module 50. The surface of the cover module 50 is substantially flat, which is conducive to installing the lens assembly 2 on the surface of the cover module 50. Moreover, the cover module 50 may also serve as the carrier for some wiring layers, thereby increasing the flexibility of the RDL process. In some embodiments, the third wiring layer 52 includes a conductive material, and the conductive material may include a conductive ink or a metal material. The third wiring layer 52 may be formed by defining a wiring pattern in the packaging body 31 and filling the conductive material in the circuit pattern. In the embodiment, conductive material is formed by conductive ink spraying or copper electroplating.

Furthermore, the fifth surface 51A of the glass cover plate 51 defines a groove 510. When viewed along the thickness direction of the glass cover plate 51, the groove 510 at least partially overlaps with the photosensitive area 21. Thus, the glass cover plate 51 can protects the photosensitive area 21 of the photosensitive chip 20. Also, by defining the groove 510 on the fifth surface 51A, the thickness of some areas of the glass cover plate 51 can be reduced to form a filter. The filter may absorb and remove a portion of the light within a certain wavelength while allowing the remaining portion of the light to pass through. In some embodiments, the cover module 50 may further include at least one of a first film layer 53 and a second film layer 54. The first film layer 53 is located on a bottom surface of the groove 510, and the second film layer 54 is located on the sixth surface 51B. When viewed along the above thickness direction, the first film layer 53 at least partially overlaps with the photosensitive area 21, and the second film layer 54 at least partially overlaps with the photosensitive area 21. As such, the thinned glass cover plate 51, the first film layer 53, and the second film layer 54 cooperatively constitute a filter, and the first film layer 53 and the second film layer 54 are located on two opposite surfaces of the thinned glass cover plate 51, respectively. The first film layer 53 and the second film layer 54 may include a material depending on the function of the filter. For example, when the filter is an infrared cut-off filter that removes the light within the infrared wavelength, the first film layer 53 and the second film layer 54 may include a material selected from a group consisting of indium tin oxide (ITO), silicon nitride (Si₃N₄), titanium dioxide (TiO₂), and any combination thereof.

In some embodiments, the photoelectric packaging structure 100 further includes a sealing material 60 provided between the fourth surface 31B and the fifth surface 51A. The sealing material 60 surrounds the second conductive pad 3201, the third conductive pad 3202, and the fifth conductive pad 520. The sealing material 60 bonds the cover module 50 to the plastic packaging module 30 to form a sealing cavity, thereby isolating external moisture or impurities and providing sealing protection for the photosensitive area 21. In the embodiment, the sealing material 60 may include a sealant.

A manufacturing method of the photoelectric packaging structure 100 in accordance with an embodiment. The method is provided by way of embodiments, as there are a variety of ways to carry out the method. The method can begin at step S1.

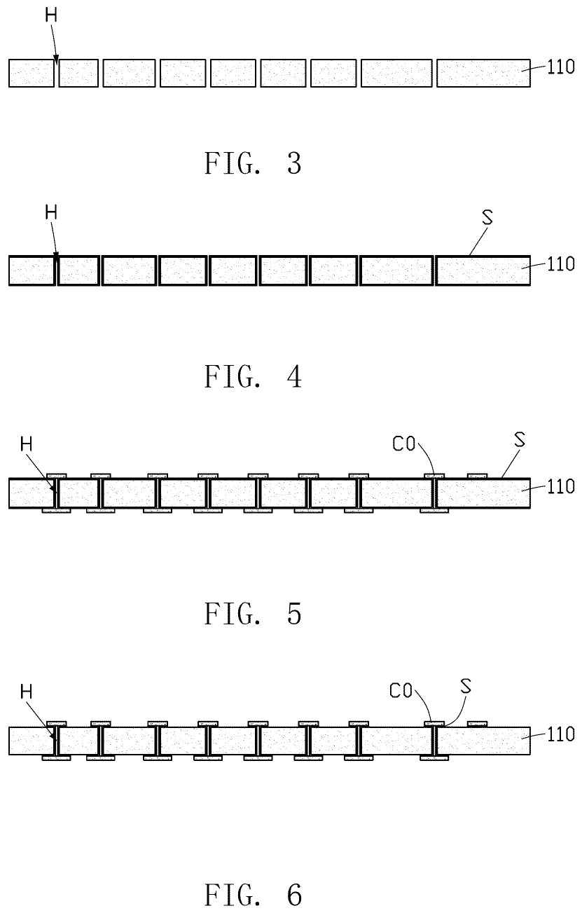

At step S1, referring to FIGS. 3 to 9, a first conductive structure 12 is formed in the glass substrate 11 to obtain a substrate module 10. The glass substrate 11 includes a first surface 11A and a second surface 11B opposite to each other. The first conductive structure 12 includes a first wiring layer 120, and the first wiring layer 120 is exposed from the second surface 11B and includes a first conductive pad 1201.

In some embodiments, the first conductive structure 12 further includes a fourth conductive channel 121 and a second solder pad 122. The fourth conductive channel 121 is formed in the glass substrate 11, and the second solder pad 122 is exposed from the first surface 11A. Two ends of the fourth conductive channel 121 are connected to the first conductive pad 1201 and the second solder pad 122, respectively.

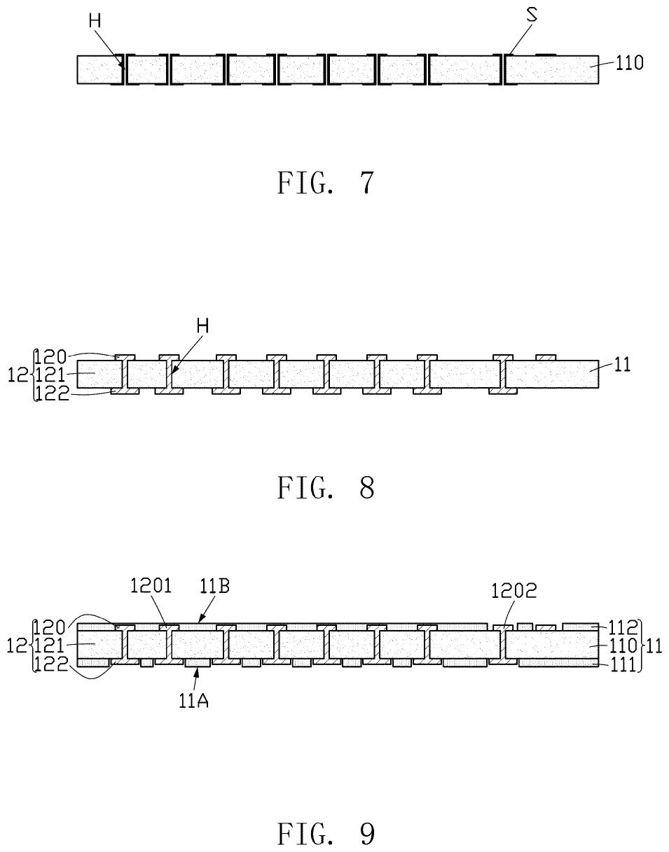

The substrate module 10 may be formed by defining a number of through holes H in the first glass body 110 (shown in FIG. 3), and each through hole H extends through two opposite surfaces of the first glass body 110. Then, a seed layer S is electroplated on the first glass body 110 (as shown in FIG. 4), and the seed layer S is also formed on the inner wall of the through holes H. Then, a third mask C3 covers the seed layer S (as shown in FIG. 5), and the third mask C3 shields the through holes H and the areas of the opposite surfaces of the first glass body 110 adjacent to the through holes. The seed layer S exposed from the third mask C3 is etched and removed (as shown in FIG. 6), and the third mask C3 is removed (as shown in FIG. 7), such that the remaining seed layer S is formed on the inner wall of the through hole H and on a portion of the opposite surfaces of the first glass body 110 adjacent to the through hole H. Then, a conductive material is formed on the seed layer S and solidified. Thus, the seed layer S and the conductive material each located in the through hole H cooperatively constitute a fourth conductive channel 121. The seed layer S and the conductive material each located on the surface of the first glass body 110 cooperatively constitute a first wiring layer 120 or a second solder pad 122 (as shown in FIG. 8). The conductive material of the first conductive structure 12 may be formed by conductive ink spraying or copper electroplating. For example, the hollow channel may be completely filled with the conductive material to form the fourth conductive channel 121. In other embodiments, a conductive layer, which is formed by solidifying the conductive material, may also be formed on the inner wall of the hollow channel, thereby forming the fourth conductive channel 121 that is hollow.

Subsequently, as shown in FIG. 9, a first protective film 111 and a second protective film 112 may be formed on the opposite surfaces of the first glass body 110, respectively. The first protective film 111 covers the sidewall of the first solder pad 1202, and the second protective film 112 covers the sidewall of the first conductive pad 1201. The first protective film 111 and the second protective film 112 provide insulation protection for the first glass body 110. As such, the first glass body 110, the first protective film 111, and the second protective film 112 cooperatively constitute the glass substrate 11. A surface of the first protective film 111 away from the first glass body 110 is the first surface 11A, and a surface of the second protective film 112 away from the first glass body 110 is the second surface 11B.

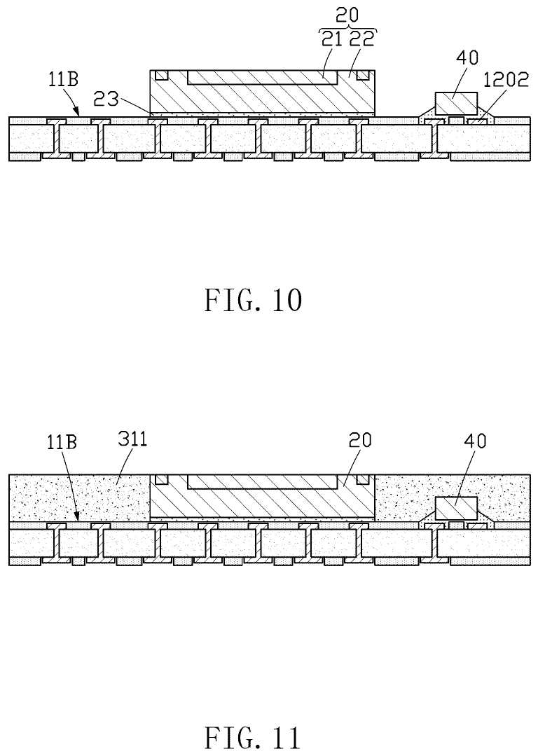

Step S2, referring to FIG. 10, a photosensitive chip 20 is formed on the second surface 11B. The photosensitive chip 20 includes a photosensitive area 21 and a non-photosensitive area 22 connected to each other.

In some embodiments, the photosensitive chip 20 may be fixed to the second surface 11B through an adhesive layer 23.

In some embodiments, when the first wiring layer 120 further includes the first solder pad 1202, after forming the photosensitive chip 20, an electronic component 40 may also be mounted on the first solder pad 1202. The electronic component 40 may be mounted to the first solder pad 1202 by solder paste. The electronic component 40 may be a passive component or an active component. The passive components may include a resistor, a capacitor, etc. The active component may include a transistor, an integrated circuit, a picture tube, etc.

Step S3, referring to FIGS. 11 and 12, a packaging body 31 is formed on the second surface 11B, and the packaging body 31 covers the photosensitive chip 20.

When the electronic component 40 is mounted on the first solder pad 1202, the packaging body 31 may further cover the electronic component 40.

In some embodiments, the packaging body 31 may be formed by first forming a first packaging block 311 on the second surface 11B (as shown in FIG. 11), and the first packaging block 311 is at least adhered to the sidewall of the photosensitive chip 20. Then, a second packaging block 312 is formed on the first packaging block 311 (as shown in FIG. 12), and the second packaging block 312 further covers the non-photosensitive area 22. The first packaging block 311 and the second packaging block 312 cooperative constitute the packaging body 31. A surface of the first packaging block 311 away from the second packaging block 312 is the third surface 31A, and a surface of the second packaging block 312 away from the first packaging block 311 is the fourth surface 31B. The packaging body 31 may be formed by a molding process.

Step S4, referring to FIG. 12, multiple first hollow channels P1 and multiple second hollow channels P2 are defined in the packaging body 31 by laser.

The first hollow channel P1 is formed in the first packaging block 311 and the second packaging block 312, and the second hollow channel P2 is formed in the second packaging block 312. The bottom of the first hollow channel P1 extends to the first conductive pad 1201, and the top of the first hollow channel P1 is located at the second packaging block 312. The bottom of the second hollow channel P2 extends to the non-photosensitive area 22, and the top of the second hollow channel P2 is located at the second packaging block 312. The tops of the multiple first hollow channels P1 and the multiple second hollow channels P2 may communicate with each other, and at least the tops of the first hollow channels P1 and the second hollow channels P2 cooperatively constitute a wiring pattern.

When the electronic component 40 is mounted on the first solder pad 1202, multiple third hollow channels P3 may also be defined in the packaging body 31 by laser. The bottom of the third hollow channel P3 extends to the electronic component 40, and the top of the third hollow channel P3 is located at the second packaging body block 312. The tops of the first hollow channels P1, the second hollow channels P2, and the third hollow channels P3 may communicate with each other to form the above wiring pattern.

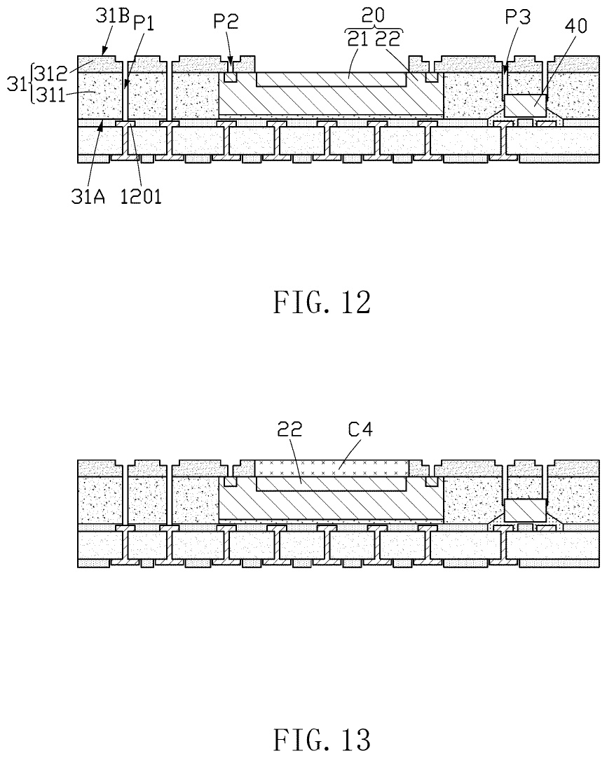

Step S5, referring to FIGS. 13 to 15, a conductive material is filled into each first hollow channel P1 and each second hollow channel P2. The conductive material is solidified to obtain a second conductive structure 32.

The second conductive structure 32 includes a first conductive channel 321, a second conductive channel 322, a second conductive pad 3201, and a third conductive pad 3202. The second conductive pad 3201 is formed at the top of the first hollow channel P1, and the third conductive pad 3202 is formed at the top of the second hollow channel P2. The first conductive channel 321 and the second conductive channel 322 are formed in the packaging body 31. The second conductive pad 3201 and the third conductive pad 3202 are exposed from the fourth surface 31B and electrically connected to each other. The two ends of the first conductive channel 321 are connected to the first conductive pad 1201 and the second conductive pad 3201, respectively. The two ends of the second conductive channel 322 are connected to the non-photosensitive area 22 and the third conductive pad 3202, respectively. Therefore, the electrical connection is achieved between the photosensitive chip 20 and the substrate module 10.

When the packaging body 31 is further provided with the third hollow channel P3, the conductive material may also be filled in the third hollow channel P3 and solidified to obtain a third conductive channel 323 and a fourth conductive pad 3203. The fourth conductive pad 3203 is formed at the top of the third hollow channel P3. The third conductive channel 323 is formed in the packaging body 31. The fourth conductive pad 3203 is exposed from the fourth surface 31B and electrically connected to the third conductive pad 3202. The two ends of the third conductive channel 323 are connected to the electronic component 40 and the fourth conductive pad 3203, respectively, such that the photosensitive chip 20 is electrically connected to the electronic component 40. The conductive material of the second conductive structure 32 may be formed by conductive ink spraying or copper electroplating. For example, the hollow channel may be completely filled with the conductive material to form the first conductive channel 321, the second conductive channel 322, and the third conductive channel 323. In other embodiments, a conductive layer, which is formed by solidified the conductive material, may also be formed on the inner walls of the hollow channel, thereby forming the first conductive channel 321, the second conductive channel 322, and the third conductive channel 323.

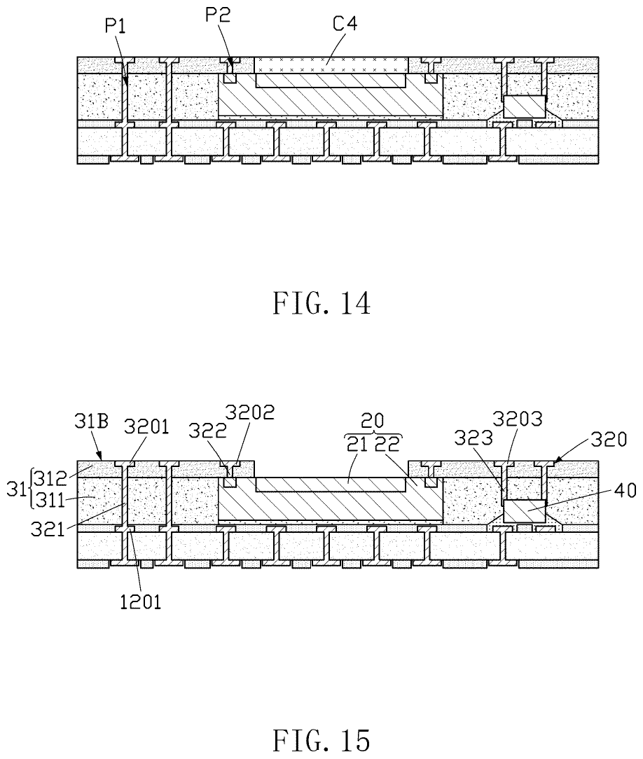

In some embodiments, before filling the conductive material, a fourth mask C4 first covers the photosensitive area 21 (as shown in FIG. 13), and then the conductive material is filled in the first hollow channel P1 and the second hollow channel P2, respectively (as shown in FIG. 14), thereby reducing the risk of the conductive material contaminating the photosensitive area 21. After the conductive material is solidified, the fourth mask C4 is removed (as shown in FIG. 15).

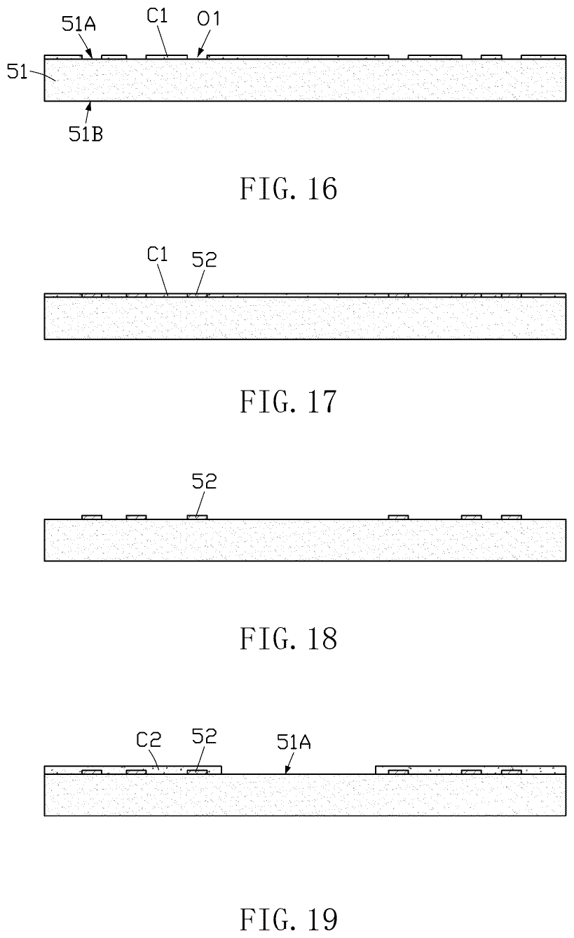

Step S6, referring to FIGS. 16 to 20, a cover module 50 is provided. The cover module 50 includes a glass cover plate 51 and a third wiring layer 52 formed on the glass cover plate 51. The glass cover plate 51 includes a fifth surface 51A and a sixth surface 51B opposite to the fifth surface 51A. The third wiring layer 52 is exposed from the fifth surface 51A and includes a fifth conductive pad 520.

In some embodiments, the cover module 50 may be formed by first forming a first mask C1 on the fifth surface 51A of the glass cover plate 51, and the first mask C1 has a first patterned opening O1. Then, the conductive material is filled in the first patterned opening O1 and solidified to obtain the third wiring layer 52 (as shown in FIG. 17), and the first mask C1 is removed (as shown in FIG. 18).

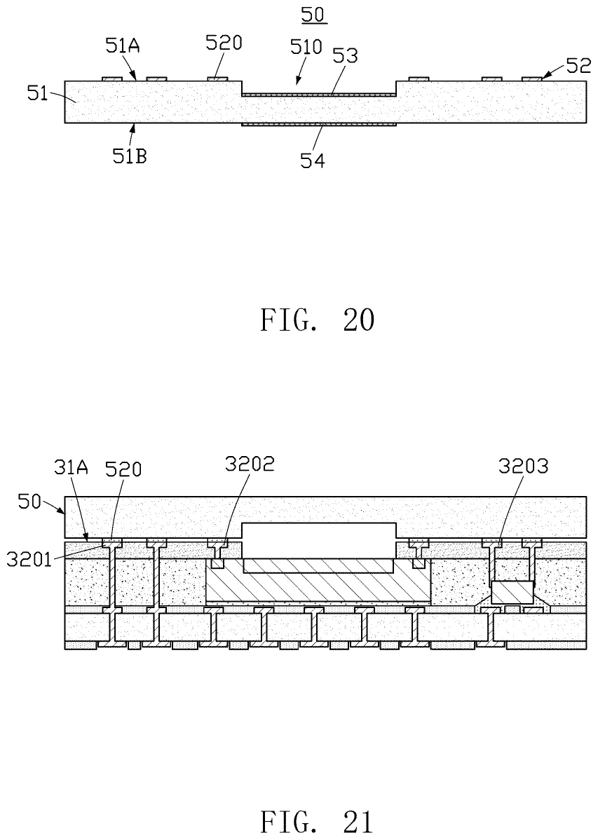

After removing the first mask C1, a second mask C2 may also be covered on the third wiring layer 52 (as shown in FIG. 19). The second mask C2 has a groove for exposing a portion of the fifth surface 51A. Then, a groove 510 is defined at the exposed fifth surface 51A (as shown in FIG. 20). After the groove 510 is formed, a first film layer 53 is formed on the bottom surface of groove 510. In some embodiments, a second film layer 54 may also be formed on the sixth surface 51B.

Step S7, referring to FIG. 21, the cover module 50 is formed on the fourth surface 31B, such that the fifth surface 51A of the glass cover plate 51 faces the fourth surface 31B, and the fifth conductive pad 520 is selectively connected to the second conductive pad 3201 or the third conductive pad 3202. The fifth conductive pad 520 can connect the second conductive pad 3201 to the third conductive pad 3202, thereby electrically connecting the photosensitive chip 20 to the substrate module 10.

When the second conductive structure 32 further includes the fourth conductive pad 3203, the fifth conductive pad 520 may also be selectively connected to the fourth conductive pad 3203. The fifth conductive pad 520 can be fixed to the second conductive pad 3201, the third conductive pad 3202, or the fourth conductive pad 3203 by solder paste.

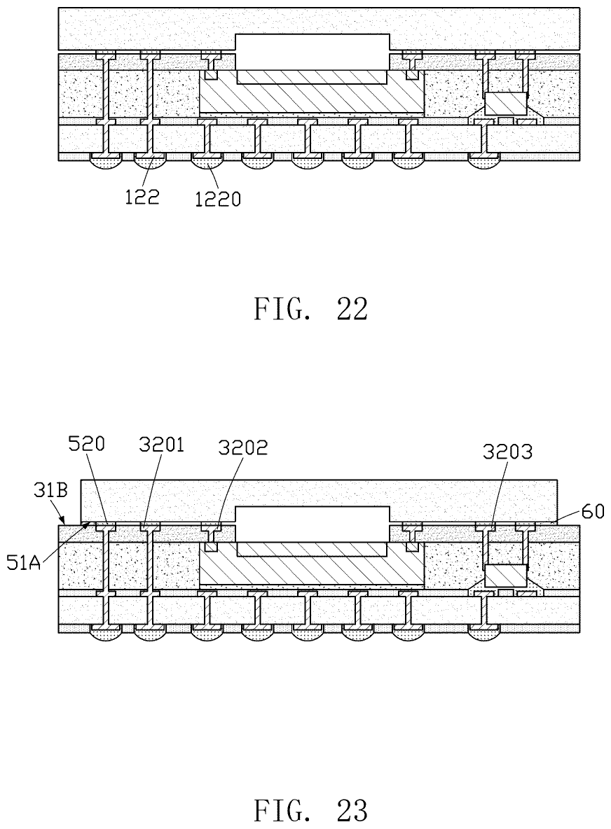

In some embodiments, as shown in FIG. 22, a solder ball 1220 may further be formed on the second solder pad 122.

Step S8, referring to FIG. 23 and FIG. 2, a sealing material 60 is formed between the fourth surface 31B and the fifth surface 51A, and the sealing material 60 surrounds the second conductive pad 3201, the third conductive pad 3202, and the fifth conductive pad 520. Then, the photoelectric packaging structure 100 is obtained.

In some embodiments, an edge region of the cover module 50 is first removed, and the sealing material 60 is formed between the fourth surface 31B and the fifth surface 51A (as shown in FIG. 23). Then, edge regions of the substrate module 10 and the plastic packaging module 30 are removed to obtain the photoelectric packaging structure 100 shown in FIG. 2.

### Second Embodiment

Referring to FIG. 30, a photoelectric packaging structure 200 is provided according to another embodiment of the present disclosure. The difference from the above photoelectric packaging structure 100 includes the structure of the substrate module 10. Specifically, the first conductive pad 1201 of the substrate module 10 includes a first end surface 1201A facing the first glass body 110, a second end surface 1201B opposite to the first end surface 1201A, and a side surface 1201C connecting the first end surface 1201A to the second end surface 1201B. The second protective film 112 covers and adheres to the first end surface 1201A, the second end surface 1201B, and the side surface 1201C. The first conductive channel 321 further extends through the second protective film 112 on the second end surface 1201B to connect to the first conductive pad 1201.

A manufacturing method of the photoelectric packaging structure 200 is also provided according to another embodiment of the present disclosure. The difference from the above manufacturing method in the first embodiment includes the manufacturing steps of the substrate module 10.

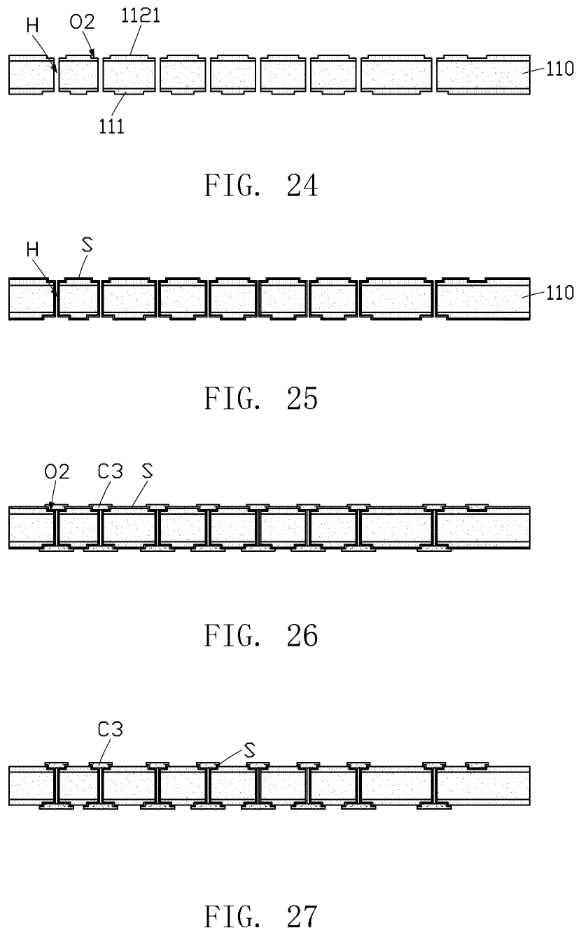

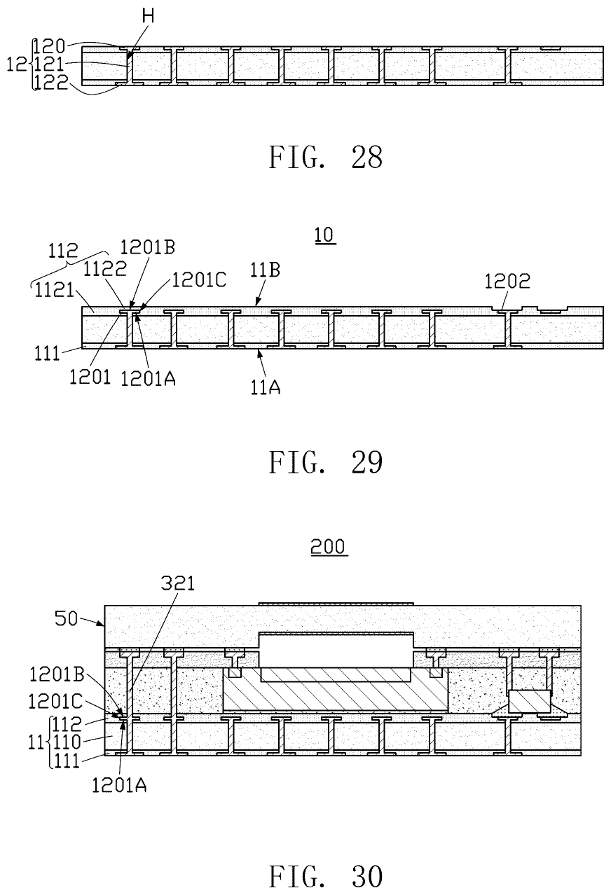

In the embodiment, the substrate module 10 may be formed by first defining a through hole H in the first glass body 110, and forming a first protective film 111 and a first protective layer 1121 on the opposite surfaces of the first glass body 110, respectively (as shown in FIG. 24). The first protective layer 1121 has a second patterned opening O2 communicating with the through hole H. Then, a seed layer S is formed on the first glass body 110, and the seed layer S is also formed on the inner wall of the through hole H and in the second patterned opening O2 (as shown in FIG. 25). Then, a third mask C3 covers the seed layer S (as shown in FIG. 26), and the third mask C3 shields the second patterned opening O2. The seed layer S exposed from the third mask C3 is etched (as shown in FIG. 27), and the third mask C3 is removed, such that the remaining seed layer S is located on the inner wall of the through hole H and in the second patterned opening O2. Finally, the conductive material is formed on the seed layer S and solidified. The seed layer S and the conductive material located in the through hole H cooperative form the fourth conductive channel 121. The seed layer S and the conductive material located in the second patterned opening O2 cooperative form the first wiring layer 120 or the second solder pad 122 (as shown in FIG. 28). Therefore, in the embodiment, the setting of the first protective layer 1121 facilitates the forming of the first wiring layer 120 on the first glass body 110. The first protective layer 1121 also provides insulation protection to the first glass body 110. There is no need to remove the first protective layer 1121 subsequently, which reduces the process cost.

Subsequently, as shown in FIG. 29, a second protective layer 1122 may also be formed on the first protective layer 1121. The first protective layer 1121 and the second protective layer 1122 cooperatively constitute the second protective film 112. The second protective film 112 covers and adheres to the first end surface 1201A, the second end surface 1201B, and the side surface 1201C of the first conductive pad 1201. The second protective film 112 also covers and adheres to the two end surfaces and the side surfaces of the first solder pad 1202. To facilitate the installation of the electronic components 40 on the first solder pad 1202, the second protective film 112 may be partially removed to expose the end surface of the first solder pad 1202.

At this time, the first glass body 110, the first protective film 111, and the second protective film 112 cooperatively constitute the glass substrate 11. A surface of the first protective film 111 away from the first glass body 110 is the first surface 11A, and a surface of the second protective film 112 away from the first glass body 110 is the second surface 11B. Referring to FIG. 29, at this time, the first conductive channel 321 further extends through a portion of the second protective film 112 to connect to the second end surface 1201B of the first conductive pad 1201.

### Third Embodiment

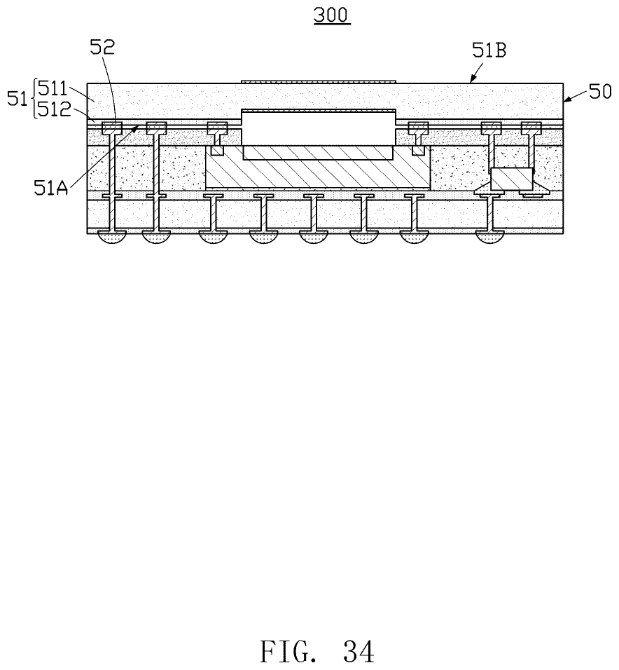

Referring to FIG. 34, a photoelectric packaging structure 300 is provided according to yet another embodiment of the present disclosure. The difference from the above photoelectric packaging structure 100 includes the structure of the cover module 50. Specifically, the glass cover plate 51 of the cover module 50 includes a second glass body 511 and a third protective film 512 formed on the second glass body 511. The third wiring layer 52 is formed on the second glass body 511 and exposed from the third protective film 512. A surface of the third protective film 512 away from the second glass body 511 is the fifth surface 51A, and a surface of the second glass body 511 away from the third protective film 512 is the sixth surface 51B.

A manufacturing method of the photoelectric packaging structure 300 is also provided according to another embodiment of the present disclosure. The difference from the above manufacturing method in the first embodiment includes the manufacturing steps of the cover module 50.

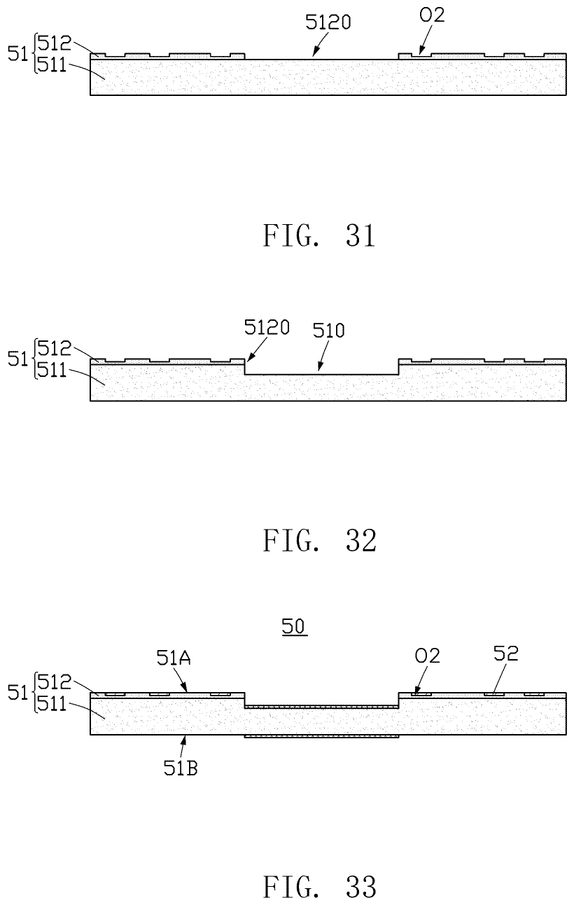

In the embodiment, the cover module 50 may be formed by first covering a third protective film 512 on the second glass body 511 (as shown in FIG. 31), and the third protective film 512 has a second patterned opening O2 and a slot 5120. The second glass body 511 and the third protective film 512 cooperatively constitute the glass cover plate 51. Then, the second glass body 511 is etched through the slot 5120 to form a groove 510 in the second glass body 511 (as shown in FIG. 32), and a conductive material is filled in the second patterned opening O2 and solidified to obtain the third wiring layer 52 (as shown in FIG. 33). Therefore, in the embodiment, the setting of the third protective film 512 facilitates the forming of the third wiring layer 52 on the second glass body 511. The third protective film 512 may also provide insulation protection for the second glass body 511. There is no need to remove the third protective film 512 subsequently, which reduces the process cost.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A photoelectric packaging structure comprising:
a substrate module comprising a glass substrate and a first conductive structure formed in the glass substrate, wherein the glass substrate comprises a first surface and a second surface opposite to each other, the first conductive structure comprises a first conductive pad exposed from the second surface;
a photosensitive chip located on the second surface, and comprising a photosensitive area and a non-photosensitive area connected to each other; and
a plastic packaging module located on the second surface, and comprising a packaging body covering the photosensitive chip and a second conductive structure formed in the packaging body, wherein the packaging body comprises a third surface facing the second surface and a fourth surface opposite to the third surface, the second conductive structure comprises a first conductive channel, a second conductive channel, a second conductive pad, and a third conductive pad, the first conductive channel and the second conductive channel are located in the packaging body, the second conductive pad and the third conductive pad are exposed from the fourth surface, two ends of the first conductive channel are connected to the first conductive pad and the second conductive pad, respectively, two ends of the second conductive channel are connected to the non-photosensitive area and the third conductive pad, respectively, the second conductive pad is configured to be electrically connected to the third conductive pad, thereby electrically connecting the photosensitive chip to the substrate module.

2. The photoelectric packaging structure according to claim 1, wherein the first conductive structure further comprises a first solder pad, the photoelectric packaging structure further comprises an electronic component mounted on the first solder pad, and the packaging body further covers the electronic component;
the second conductive structure further comprises a third conductive channel and a fourth conductive pad, the third conductive channel is located in the packaging body, the fourth conductive pad is exposed from the fourth surface, two ends of the third conductive channel are connected to the electronic component and the fourth conductive pad, respectively, thereby electrically connecting the fourth conductive pad to the first solder pad; the fourth conductive pad is further configured to be electrically connected to the third conductive pad, thereby electrically connecting the photosensitive chip to the electronic component.

3. The photoelectric packaging structure according to claim 1, further comprising:
a cover module located on the fourth surface, and comprising a glass cover plate and a fifth conductive pad formed on the glass cover plate, wherein the glass cover plate comprises a fifth surface facing the fourth surface and a sixth surface opposite to the fifth surface, the fifth conductive pad is exposed from the fifth surface and selectively connected to the second conductive pad or the third conductive pad.

4. The photoelectric packaging structure according to claim 3, wherein the fifth surface defines a groove, and the groove at least partially overlaps with the photosensitive area.

5. The photoelectric packaging structure according to claim 4, wherein the cover module further comprises a first film layer and a second film layer, the first film layer is located on a bottom surface of the groove, the second film layer is located on the sixth surface, the first film layer at least partially overlaps with the photosensitive area, and the second film layer at least partially overlaps with with the photosensitive area.

6. The photoelectric packaging structure according to claim 3, further comprising:
a sealing material formed between the fourth surface and the fifth surface, and surrounding the second conductive pad, the third conductive pad, and the fifth conductive pad.

7. The photoelectric packaging structure according to claim 1, wherein the packaging body comprises a first packaging block and a second packaging block, the first packaging block is located on the second surface and at least adhered to a sidewall of the photosensitive chip, the second packaging block is located on the first packaging block and covers the non-photosensitive area, a surface of the first packaging block away from the second packaging block is the third surface, a surface of the second packaging block away from the first packaging block is the fourth surface, the first conductive channel is formed in the first packaging block and the second packaging block, and the second conductive channel is formed in the second packaging block.

8. The photoelectric packaging structure according to claim 1, wherein the first conductive structure further comprises a fourth conductive channel and a second solder pad, the fourth conductive channel is formed in the glass substrate, the second solder pad is exposed from the first surface, two ends of the fourth conductive channel are connected to the first conductive pad and the second solder pad, respectively, and a solder ball is provided on the second solder pad.

9. The photoelectric packaging structure according to claim 8, wherein the glass substrate comprises a first glass body, a first protective film, and a second protective film, the first glass body is located between the first protective film and the second protective film, the fourth conductive channel is defined in the first glass body, a surface of the first protective film away from the first glass body is the first surface, and a surface of the second protective film away from the first glass body is the second surface.

10. A manufacturing method of a photoelectric packaging structure, comprising:
forming a first conductive structure on a glass substrate to obtain a substrate module, the glass substrate comprising a first surface and a second surface opposite to each other, the first conductive structure comprising a first conductive pad exposed from the second surface;
forming a photosensitive chip on the second surface, the photosensitive chip comprising a photosensitive area and a non-photosensitive area connected to each other;
forming a packaging body on the second surface, causing the packaging body to cover the photosensitive chip, the packaging body comprising a third surface facing the second surface and a fourth surface opposite to the third surface;
defining a first hollow channel and a second hollow channel in the packaging body by laser, wherein a bottom of the first hollow channel extends to the first conductive pad, a bottom of the second hollow channel extends to the non-photosensitive area, a top of the first hollow channel communicate with a top of the second hollow channel;
filling a conductive material in the first hollow channel and solidifying the conductive material to obtain a first conductive channel and a second conductive pad, wherein the second conductive pad is formed at the top of the first hollow channel; and
filling a conductive material in the second hollow channel and solidifying the conductive material to obtain a second conductive channel and a third conductive pad, wherein the third conductive pad is formed at the top of the second hollow channel, the first conductive channel and the second conductive channel are formed in the packaging body, the second conductive pad and the third conductive pad are exposed from the fourth surface and electrically connected to each other, two ends of the first conductive channel are connected to the first conductive pad and the second conductive pad, respectively, two ends of the second conductive channel are connected to the non-photosensitive region and the third conductive pad, respectively, thereby electrically connecting the photosensitive chip to the substrate module.

11. The manufacturing method according to claim 10, wherein the first conductive structure further comprises a first solder pad, and before forming the packaging body on the second surface, the manufacturing method further comprises:
mounting an electronic component on the first solder pad, such that after forming the packaging body on the second surface, the packaging body further covers the electronic component, and the manufacturing method further comprises:
defining a third hollow channel in the packaging body by laser, wherein a bottom of the third hollow channel extends to the electronic component, and a top of the third hollow channel communicates with to the top of the second hollow channel; and
filling a conductive material in the third hollow channel and solidifying the conductive material to obtain a third conductive channel and a fourth conductive pad, wherein the fourth conductive pad is formed at the top of the third hollow channel, the third conductive channel is formed in the packaging body, the fourth conductive pad is exposed from the fourth surface and electrically connected to the third conductive pad, two ends of the third conductive channel are connected to the electronic component and the fourth conductive pad, respectively, thereby electrically connecting the photosensitive chip to the electronic component.

12. The manufacturing method according to claim 10, wherein after filling the conductive material, the manufacturing method further comprises:
forming a cover module on the fourth surface, wherein the cover module comprises a glass cover and a fifth conductive pad formed on the glass cover, the glass cover comprises a fifth surface facing the fourth surface and a sixth surface opposite to the fifth surface, the fifth conductive pad is exposed from the fifth surface and selectively connected to the second conductive pad or the third conductive pad.

13. The manufacturing method according to claim 12, wherein a manufacturing method of the cover module comprises:
covering a first mask on the fifth surface, the first mask having a first patterned opening;
filling a conductive material in the first patterned opening and solidifying the conductive material to obtain the fifth conductive pad; and
removing the first mask.

14. The manufacturing method according to claim 13, wherein after removing the first mask, the manufacturing method further comprises:
covering a second mask on the fifth conductive pad, and the second mask having a slot for partially exposing the fifth surface;
defining a groove at the exposed fifth surface, wherein the groove at least partially overlaps with the photosensitive area; and
removing the second mask.

15. The manufacturing method according to claim 12, wherein a manufacturing method of the cover module comprises:
covering a third protective film on a second glass body, wherein the third protective film has a second patterned opening, and the second glass body and the third protective film cooperatively constitute the glass cover plate; and
filling a conductive material in the second patterned opening and solidifying the conductive material to obtain the fifth conductive pad.

16. The manufacturing method according to claim 12, wherein after forming the cover module on the third surface, the manufacturing method further comprises:
forming a sealing material between the fourth surface and the fifth surface, thereby causing the sealing material to surround the second conductive pad, the third conductive pad, and the fifth conductive pad.

17. The manufacturing method according to claim 10, wherein forming the packaging body on the second surface comprises:
forming a first packaging block on the second surface, wherein the first packaging block is at least adhered to a sidewall of the photosensitive chip;
forming a second packaging block on the first packaging block, thereby causing the second packaging block to further cover the non-photosensitive area, wherein the first packaging block and the second packaging block cooperatively constitute the plastic sealing body, a surface of the first packaging block away from the second packaging block is the third surface, a surface of the second packaging block away from the first packaging block is the fourth surface, the first hollow channel is defined in the first packaging block and the second packaging block, and the second hollow channel is defined in the second packaging block.

18. The manufacturing method according to claim 10, wherein forming the first conductive structure on the glass substrate comprises:
defining a through hole in the first glass body;
forming a seed layer on an inner wall of the through hole, thereby causing the seed layer to extend to an area of two opposite surfaces of the first glass body adjacent to the through hole; and
forming a conductive material on the seed layer and solidifying the conductive material, wherein the seed layer and the conductive material located in the through hole cooperatively constitute a fourth conductive channel, and the seed layer and the conductive material located on the surfaces of the first glass body cooperatively constitute the first conductive pad.

19. The manufacturing method according to claim 18, wherein after forming the conductive material on the seed layer, the manufacturing method further comprises:
forming a first protective film and a second protective film on the surfaces of the first glass body, respectively, thereby causing the first conductive pad to be exposed from the second protective film, wherein the first glass body, the first protective film, and the second protective film cooperatively constitute the glass substrate, a surface of the first protective film away from the first glass body is the first surface, and a surface of the second protective film away from the first glass body is the second surface.

20. A camera module comprising:
a lens assembly; and
a photoelectric packaging structure according to claim 1, wherein the lens assembly is disposed on a side of the plastic packaging module of the photoelectric packaging structure away from the substrate module.
